(19) United States
(12) Patent Application Publication
(10) Pub. No.: US 2023/0017089 A1
(43) Pub. Date: Jan. 19, 2023

(54) ELECTROSTATIC DISCHARGE PROTECTION DEVICE

(71) Applicant: CHANGXIN MEMORY TECHNOLOGIES, INC., Hefei City (CN)

(72) Inventor: Qian XU, Hefei City (CN)

(21) Appl. No.: 17/647,108

(22) Filed: Jan. 5, 2022

Related U.S. Application Data
(63) Continuation of application No. PCT/CN2021/113181, filed on Aug. 18, 2021.

(30) Foreign Application Priority Data
Jul. 16, 2021 (CN) 202110808153.9

(51) Int. Cl. H01L 27/02; H01L 29/732

(52) U.S. Cl. CPC H01L 27/0262; H01L 29/732

(57) ABSTRACT

The present disclosure provides an electrostatic discharge protection device, and relates to the technical field of semiconductors. A first P-type heavily-doped region and a first N-type heavily-doped region of the electrostatic discharge protection device are located in a P well, a second P-type heavily-doped region and a third N-type heavily-doped region are located in a first N well, one part of a second N-type heavily-doped region is located in the P well, the other part is located in the first N well, and the P well and the first N well are located in a P-type substrate. The P-type substrate is provided with a gate structure, the gate structure, the first N-type heavily-doped region, and the second N-type heavily-doped region form a transistor, the first N-type heavily-doped region and the gate structure are connected to a first voltage.

### CROSS-REFERENCE TO RELATED APPLICATIONS

This is a continuation of International Application No. PCT/CN2021/113181, filed on Aug. 18, 2021, which claims the priority to Chinese Patent Application No. 202110808153.9, titled “ELECTROSTATIC DISCHARGE PROTECTION DEVICE”, filed with the China National Intellectual Property Administration (CNIPA) on Jul. 16, 2021. The entire contents of International Application No. PCT/CN2021/113181 and Chinese Patent Application No. 202110808153.9 are incorporated herein by reference.

### TECHNICAL FIELD

The present disclosure relates but not only to an electrostatic discharge protection device.

### BACKGROUND

Electro static discharge (ESD) is one of factors affecting reliability of integrated circuits (ICs). From chip manufacturing to production assembly, from product transportation to daily use, an electronic product is accompanied by occurrence of an ESD phenomenon in an entire life cycle. When ESD occurs, a high voltage instantaneously generated breaks down a device in an IC, causing a chip to fail or to burn out.

To avoid the harm of the ESD to the IC, an electrostatic discharge protection device is usually provided in the IC, and the IC is protected by releasing electrostatic charges through a low impedance channel formed by the electrostatic discharge protection device. The electrostatic discharge protection device generally includes one or more of a resistor, a diode, a triode, a metal oxide semiconductor (MOS) transistor, or a semiconductor conductor rectifier (SCR). However, existing electrostatic discharge protection devices have a problem of high trigger voltage and are not suitable for electrostatic discharge protection of semiconductor devices such as a dynamic random access memory (DRAM).

### SUMMARY

The present disclosure provides an electrostatic discharge protection device, including a first subdevice. The first subdevice includes: a first P-type heavily-doped region, a first N-type heavily-doped region, a second N-type heavily-doped region, a second P-type heavily-doped region, and a third N-type heavily-doped region. Both the first P-type heavily-doped region and the first N-type heavily-doped region are located in a P well, both the second P-type heavily-doped region and the third N-type heavily-doped region are located in a first N well, one part of the second N-type heavily-doped region is located in the P well, the other part of the second N-type heavily-doped region is located in the first N well, the P well is adjacent to the first N well, and both the P well and the first N well are located in a P-type substrate. The P-type substrate is provided with a gate structure, the gate structure is located between the first N-type heavily-doped region and the second N-type heavily-doped region, and the gate structure, the first N-type heavily-doped region, and the second N-type heavily-doped region form a transistor. The first N-type heavily-doped region and the gate structure are connected to a first voltage, and the second N-type heavily-doped region and the second P-type heavily-doped region are connected to a second voltage.

### BRIEF DESCRIPTION OF THE DRAWINGS

FIG. 1 is a layout diagram of an electrostatic discharge protection device according to an embodiment of the present disclosure;

FIG. 2 is a schematic structural diagram of an electrostatic discharge protection device according to an embodiment of the present disclosure; and

FIG. 3 is a diagram of a working principle of an electrostatic discharge protection device according to an embodiment of the present disclosure.

### DETAILED DESCRIPTION

Exemplary embodiments are described in detail herein, and examples thereof are represented in the accompanying drawings. When the following descriptions relate to the accompanying drawings, unless otherwise stated, same digitals in different accompanying drawings represent same or similar essential factors. Implementations described in the following exemplary embodiments do not represent all implementations consistent with the present disclosure. On the contrary, the implementations are merely examples of apparatuses and methods that are described in detail in the appended claims and consistent with some aspects of the present disclosure.

The terms “includes” and “has” in the present disclosure are used to indicate an open-ended inclusion and to mean that additional elements/components/and the like may exist in addition to the listed elements/components/and the like. The terms “first”, “second”, and the like are merely used as markers, not as quantitative restrictions on objects thereof. In the present disclosure, in the absence of any description to the contrary, orientation terms such as “upper, lower, left, right” are usually used to refer to the upper, lower, left, and right as shown in the accompanying drawings. The “inside and outside” refers to the inside and outside relative to contour of each component. It can be understood that the above orientation terms represent relative terms and are used in this specification for convenience only, for example, according to orientations in the examples described in the accompanying drawings, if a device of an icon is turned upside down, the components described as “upper” will become the “lower” components. In the accompanying drawings, shapes shown can be deformed depending on a manufacturing process and/or a tolerance. Therefore, the exemplary implementations of the present disclosure are not limited to the particular shapes illustrated in the accompanying drawings and may include changes in shape caused during a manufacturing process. In addition, the different elements and regions in the accompanying drawings are shown schematically only, and therefore the present disclosure is not limited to the sizes or distances shown in the accompanying drawings.

ESD phenomena often occur in IC products. For example, in a production, manufacturing, and transportation processes of an IC chip, the IC chip often accumulates electrostatic charges itself or due to an environment. When a pin of the IC chip is directly or indirectly grounded, electrostatic charges are discharged through the pin. This process is completed instantaneously, and an instantaneously high voltage or high current damages a semiconductor device. Therefore, in the prior art, an electrostatic discharge protection device is provided in the semiconductor device.

However, a trigger voltage of the electrostatic discharge protection device in the prior art is usually high, and a breakdown voltage of a PN junction or gate oxide layer in the IC chip is lower than the trigger voltage. When in an electrostatic environment, the IC chip is damaged or burned before the electrostatic discharge protection device is triggered. Therefore, the trigger voltage of the electrostatic discharge protection device needs to be reduced to improve an electrostatic discharge protection capability of the electrostatic discharge protection device.

In view of the above problems, an embodiment of the present disclosure provides an electrostatic discharge protection device. A transistor is formed in the electrostatic discharge protection device, and the transistor is conducted first. In addition, a voltage of a source or a drain of the transistor rises, to speed up the conduction of the transistor, so as to discharge a part of an electrostatic current, thereby reducing the trigger voltage of the electrostatic discharge protection device and improving the electrostatic discharge protection capability of the electrostatic discharge protection device. With the conduction of the transistor, a low impedance channel is formed in the electrostatic discharge protection device, to discharge most of the electrostatic current, thereby further improving the electrostatic discharge protection capability of the electrostatic discharge protection device.

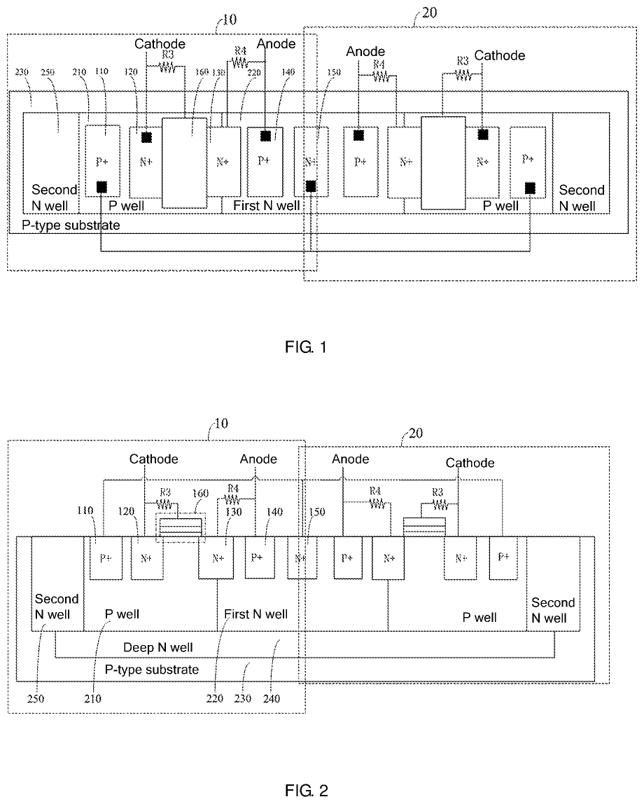

Refer to FIG. 1 and FIG. 2. FIG. 1 is a layout diagram of an electrostatic discharge protection device according to an embodiment of the present disclosure. FIG. 2 is a schematic structural diagram of an electrostatic discharge protection device according to an embodiment of the present disclosure. As shown in FIG. 1 and FIG. 2, the electrostatic discharge protection device includes a first subdevice 10. The first subdevice 10 includes: a first P-type heavily-doped region 110, a first N-type heavily-doped region 120, a second N-type heavily-doped region 130, a second P-type heavily-doped region 140, and a third N-type heavily-doped region 150. The heavily-doped region is a region in which a large quantity of impurities are doped, that is, a doping concentration is high. The P-type heavily-doped region is referred to as P+ for short, and the N-type heavily-doped region is referred to as N+ for short.

In some possible examples, the second N-type heavily-doped region 130 is located between the first P-type heavily-doped region 110 and the second N-type heavily-doped region 130, and the second P-type heavily-doped region 140 is located between the second N-type heavily-doped region 130 and the third N-type heavily-doped region 150. Along a left-to-right direction in FIG. 1 and FIG. 2, in the first subdevice 10, the first P-type heavily-doped region 110, the first N-type heavily-doped region 120, the second N-type heavily-doped region 130, the second P-type heavily-doped region 140, and the third N-type heavily-doped region 150 are sequentially arranged.

As shown in FIG. 1 and FIG. 2, both the first P-type heavily-doped region 110 and the first N-type heavily-doped region 120 are located in a P well 210, both the second P-type heavily-doped region 140 and the third N-type heavily-doped region 150 are located in a first N well 220, and the P well 210 is adjacent to the first N well 220. As an orientation shown in FIG. 1 and FIG. 2, the P well 210 is located on a left side of the first N well 220. One part of the second N-type heavily-doped region 130 is located in the P well 210, and the other part of the second N-type heavily-doped region 130 is located in the first N well 220, that is, the second N-type heavily-doped region 130 straddles the P well 210 and the first N well 220. Both the P well 210 and the first N well 220 are located in a P-type substrate 230.

The P-type substrate 230 is a P-type semiconductor (hole-type semiconductor) substrate, and a material of the P-type substrate 230 may be silicon, germanium, gallium arsenide (GaAs), indium phosphide (InP), gallium nitride (GaN), or the like. The first N well 220 may be formed through implantation of N-type ions by busing an ion implantation process, and the P well 210 may be formed through implantation of P-type ions by using an ion implantation process.

In some possible examples of the present disclosure, both the P well 210 and the first N well 220 are located in a deep N well 240, and the deep N well 240 is located at the P-type substrate 230, for example, the deep N well 240 is formed by implanting N-type ions in the P-type substrate 230. The deep N well 240 is used to isolate the first subdevice 10 from another structure, to reduce mutual impact between the electrostatic discharge protection device and another structure.

As shown in FIG. 2, the depths of the P well 210 and the first N well 220 are less than that of the deep N well 240, that is, both the bottoms of the P well 210 and the first N well 220 are higher than that of the deep N well 240. A second N well 250 is further provided on a side of the P well 210 far away from the first N well 220, the second N well 250 is adjacent to the P well 210, one part of the second N well 250 is located in the deep N well 240, and the other part of the second N well 250 is located in the P-type substrate 230. As shown in FIG. 2, a right side of the P well 210 is adjacent to the first N well 220, a left side of the P well 210 is adjacent to the second N well 250, and the second N well 250 straddles the deep N well 240 and the P-type substrate 230.

In some possible examples, the depth of the first N well 220 may be the same as that of the second N well 250, a type and a doping concentration of N-type ions in the first N well 220 may be the same as those of N-type ions in the second N well 250, to improve uniformity of the first N well 220 and the second N well 250, such that the first N well 220 and the second N well 250 are simultaneously formed. The first N well 220, the P well 210, the first N well 220, the first P-type heavily-doped region 110, the first N-type heavily-doped region 120, the second N-type heavily-doped region 130, the second P-type heavily-doped region 140, and the third N-type heavily-doped region 150 may all be formed through ion implantation.

Still refer to FIG. 1 and FIG. 2. The P-type substrate 230 is provided with a gate structure 160, the gate structure 160 is located between the first N-type heavily-doped region 120 and the second N-type heavily-doped region 130, and the gate structure 160, the first N-type heavily-doped region 120, and the second N-type heavily-doped region 130 form a transistor. The gate structure 160 is a gate of the transistor, the first N-type heavily-doped region 120 and the second N-type heavily-doped region 130 are respectively a source and a drain of the transistor. For example, the first N-type heavily-doped region 120 is the source of the transistor, and the second N-type heavily-doped region 130 is the drain of the transistor.

For example, the gate structure 160 includes an oxide layer and a conductive layer that are provided in a stack manner, where the oxide layer is provided on the P-type substrate 230. A material of the oxide layer may be silicon oxide, and a material of the conductive layer may be polycrystalline silicon. In other words, the gate structure 160, the first N-type heavily-doped region 120, and the second N-type heavily-doped region 130 form an N-metal-oxide-semiconductor (NMOS) transistor.

In this embodiment of the present disclosure, the first N-type heavily-doped region 120 and the gate structure 160 are connected to a first voltage, the second N-type heavily-doped region 130 and the second P-type heavily-doped region 140 are connected to a second voltage, where the first voltage may be a cathode voltage, and the second voltage may be an anode voltage. For example, the gate structure 160 is connected to the cathode voltage through a first resistor R3, and the second N-type heavily-doped region 130 is connected to the anode voltage through a second resistor R4. The first resistor R3 and the second resistor R4 are provided to reduce a voltage value on the gate structure 160 and the second N-type heavily-doped region 130, so as to protect the gate structure 160 and the second N-type heavily-doped region 130.

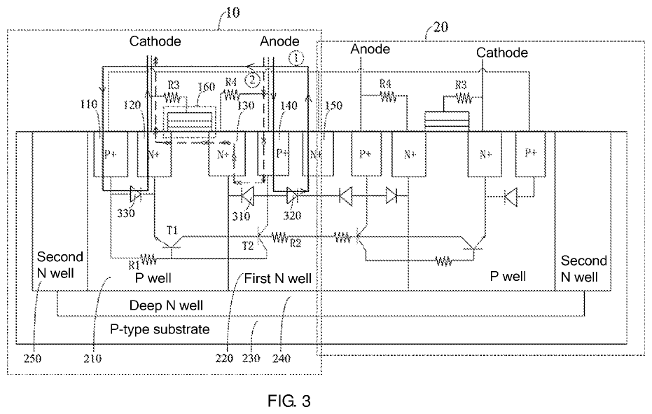

As shown in FIG. 3, the second P-type heavily-doped region 140 and the second N-type heavily-doped region 130 form a first diode 310, an anode of the first diode 310 is connected to the second P-type heavily-doped region 140, a cathode of the first diode 310 is connected to the second N-type heavily-doped region 130, and the first diode 310 and the transistor form a second discharge path. The second discharge path is represented by an arrow with a numeral 2 shown in FIG. 3. When an electrostatic current flows from the first diode 310 to the gate structure 160, the gate structure 160 is pulled up, such that a channel of the transistor is conducted, thereby discharging a part of the electrostatic current. In addition, the second N-type heavily-doped region 130 is connected to the anode voltage, to increase a voltage on the second N-type heavily-doped region 130, such that the transistor may be relatively fast conducted.

Refer to FIG. 3. The P well 210, the first N well 220, and the first N-type heavily-doped region 120 form a parasitic NPN-type transistor T1. The P well 210, the first N well 220, and the second P-type heavily-doped region 140 form a parasitic PNP-type transistor T2. The parasitic PNP-type transistor T2 and the parasitic NPN-type transistor T1 form a first discharge path.

The P well 210 has a first parasitic resistor R1. One terminal of the first parasitic resistor R1 is connected to a base of the parasitic NPN-type transistor T1. The base of the parasitic NPN-type transistor T1 is further connected to a collector of the parasitic PNP-type transistor T2. An emitter of the parasitic NPN-type transistor T1 is connected to a first voltage through the first N-type heavily-doped region 120.

The first N well 220 has a second parasitic resistor R2. One terminal of the second parasitic resistor R2 is connected to a base of the parasitic PNP-type transistor T2. The base of the parasitic PNP-type transistor T2 is further connected to a collector of the parasitic NPN-type transistor T1. The parasitic PNP-type transistor T2 is connected to a second voltage through the second P-type heavily-doped region 140.

With conduction of the transistor, a current flows through the first N well 220, and a relatively large voltage difference occurs between the base and an emitter of the parasitic PNP-type transistor T2. After the voltage difference between the base and the emitter of the parasitic PNP-type transistor T2 is greater than a saturation break over voltage of the parasitic PNP-type transistor T2, the parasitic PNP-type transistor T2 is conducted. A current of the collector of the parasitic PNP-type transistor T2 is fed back to the base of the parasitic NPN-type transistor T1, such that a relatively large voltage difference occurs between the emitter and the base of the parasitic NPN-type transistor T1. After the voltage difference between the emitter and the base of the parasitic NPN-type transistor T1 is greater than a saturation break over voltage of the parasitic NPN-type transistor T1, the parasitic NPN-type transistor T1 is conducted, and the parasitic PNP-type transistor T2 and the parasitic NPN-type transistor T1 form the first discharge path, where the first discharge path is a low impedance path, such that an electrostatic current is discharged.

In addition, the parasitic PNP-type transistor T2 is a vertical transistor, the base is the first N well 220, and tens of times gains may be obtained from the base to the collector. The parasitic NPN-type transistor T1 is a side transistor, the base is the P well 210, and tens of times gains may be obtained from the base to the collector. The first discharge path has a relatively high discharge capability by using an amplification function of the parasitic PNP-type transistor T2 and the parasitic NPN-type transistor T1, such that the electrostatic discharge protection device in this embodiment of the present disclosure has a relatively strong electrostatic discharge protection capability.

It should be noted that, shallow trench isolation regions (not drawn in the figure) are separately provided between the first P-type heavily-doped region 110 and the first N-type heavily-doped region 120, between the second N-type heavily-doped region 130 and the second P-type heavily-doped region 140, and between the second P-type heavily-doped region 140 and the third N-type heavily-doped region 150. The shallow trench isolation regions include an insulating material (silicon oxide or silicon oxynitride), to insulate the above heavily-doped regions. The tops of the shallow trench isolation regions are not lower than the top of the first P-type heavily-doped region 110, the first N-type heavily-doped region 120, the second N-type heavily-doped region 130, and the second P-type heavily-doped region 140, and the bottoms of the shallow trench isolation regions are lower than the bottom of the first P-type heavily-doped region 110, the first N-type heavily-doped region 120, the second N-type heavily-doped region 130, and the second P-type heavily-doped region 140, and is higher than the bottom of the first N well 220 and the P well 210.

To further reduce the trigger voltage of the electrostatic discharge protection device, and improve the electrostatic discharge protection capability of the electrostatic discharge protection device, in some possible examples of the present disclosure, in the first subdevice 10, the first P-type heavily-doped region 110 is electrically connected to the third N-type heavily-doped region 150.

As shown in FIG. 3, the second P-type heavily-doped region 140 and the third N-type heavily-doped region 150 form a second diode 320, an anode of the second diode 320 is connected to the second P-type heavily-doped region 140, and a cathode of the second diode 320 is connected to the third N-type heavily-doped region 150. The first P-type heavily-doped region 110 and the first N-type heavily-doped region 120 form a third diode 330, an anode of the third diode 330 is connected to the first P-type heavily-doped region 110, and a cathode of the third diode 330 is connected to the first N-type heavily-doped region 120. The second diode 320 and the third diode 330 form a third discharge path, the third discharge path is presented by an arrow with a numeral 1 shown in FIG. 3, and the electrostatic current sequentially flows through the second diode 320, the second diode 320, and the third diode 330 and is discharged.

In this embodiment of the present disclosure, when the electrostatic discharge protection device is located in an electrostatic environment, the first discharge path formed by the parasitic PNP-type transistor and the parasitic NPN-type transistor, the second discharge path formed by the first diode 310 and the transistor, and the third discharge path formed by the second diode 320, the second diode 320, and the third diode 330 are almost simultaneously conducted, such that a part of the electrostatic current is discharged, thereby reducing the trigger voltage of the electrostatic discharge protection device, and improving the electrostatic discharge protection capability of the electrostatic discharge protection device. When the electrostatic discharge protection device is located in a normal environment, the gate structure 160 of the transistor has a low potential, not affecting normal work of a circuit protected by the electrostatic discharge protection device.

In some other possible examples of the present disclosure, the electrostatic discharge protection device further includes a second subdevice 20. The second subdevice 20 has a same structure as the first subdevice 10, and the second subdevice 20 and the first subdevice 10 are symmetrically distributed with respect to an axis of symmetry.

As shown in FIG. 1 to FIG. 3, the second subdevice 20 includes: a first P-type heavily-doped region, a first N-type heavily-doped region, a second N-type heavily-doped region, a second P-type heavily-doped region, and a third N-type heavily-doped region. The second N-type heavily-doped region is located between the first N-type heavily-doped region and the second P-type heavily-doped region, and the second P-type heavily-doped region is located between the second N-type heavily-doped region and the third N-type heavily-doped region. Along a right-to-left direction in FIG. 1 and FIG. 2, in the second subdevice 20, the first P-type heavily-doped region, the first N-type heavily-doped region, the second N-type heavily-doped region, the second P-type heavily-doped region, and the third N-type heavily-doped region are sequentially arranged.

Both the first P-type heavily-doped region and the first N-type heavily-doped region are located in a P well, both the second P-type heavily-doped region and the third N-type heavily-doped region are located in a first N well, and the P well is adjacent to the first N well. In addition, both the P well and the first N well are located in a P-type substrate, one part of the second N-type heavily-doped region is located in the P well, and the other part of the second N-type heavily-doped region is located in the first N well.

In some possible examples of the present disclosure, both the P well and the first N well are located in a deep N well, and the deep N well is located on the P-type substrate. A second N well is further provided on a side of the P well far away from the first N well, the second N well is adjacent to the P well, one part of the second N well is located in the deep N well, and the other part of the second N well is located in the P-type substrate.

As shown in FIG. 1 and FIG. 2, the second subdevice 20 has the same structure as the first subdevice 10, to enable a discharge path in the second subdevice 20 to be consistent with a discharge path in the first subdevice 10, and ensure that the second subdevice 20 has a consistent feature with the first subdevice 10, such that the second subdevice 20 and the first subdevice 10 has a same trigger voltage. Therefore, the electrostatic current is more evenly discharged. The electrostatic discharge protection devices symmetrically distributed in the second subdevice 20 and the first subdevice 10 have a mutual protection capability, to improve an electrostatic discharge protection capability of the electrostatic discharge protection device, and avoid a damage caused by a reverse electrostatic current to the electrostatic discharge protection device. A working principle of the second subdevice 20 is the same as that of the first subdevice 10, and details are not described herein again.

The third N-type heavily-doped region 150 of the first subdevice 10 is located on a side of the first subdevice 10 close to the axis of symmetry, and the first subdevice 10 and the second subdevice 20 share the third N-type heavily-doped region 150. The first subdevice 10 and the second subdevice 20 may further share the first N well 220 and the P-type substrate 230.

As shown in FIG. 1 and FIG. 2, the third N-type heavily-doped region 150 of the first subdevice 10 and the third N-type heavily-doped region 150 of the second subdevice 20 are in an integrated structure, the first N well 220 of the first subdevice 10 and the first N well 220 of the second subdevice 20 are in an integrated structure, the deep N well 240 of the first subdevice 10 and the deep N well 240 of the second subdevice 20 are in an integrated structure, and the P-type substrate 230 of the first subdevice 10 and the P-type substrate 230 of the second subdevice 20 are in an integrated structure. The first subdevice 10 and the second subdevice 20 are partially overlapped, such that a layout of the electrostatic discharge protection device is more compact. In this way, a layout area of the electrostatic discharge protection device is further reduced while the electrostatic discharge protection capability of the electrostatic discharge protection device is improved.

In the electrostatic discharge protection device provided in the present disclosure, the gate structure 160, the first N-type heavily-doped region 120, and the second N-type heavily-doped region 130 form the transistor. When the electrostatic discharge protection device is located in the electrostatic environment, as the electrostatic current is increased, the PN junction formed by the second P-type heavily-doped region 140 and the P well 210 is broken down before the PN junction formed by the first N well 220 and the P well 210, that is, the transistor is first conducted. In addition, the second N-type heavily-doped region 130 of the transistor is connected to the second voltage, to increase a voltage in the second N-type heavily-doped region 130, speed up the conduction of the transistor, and discharge a part of the electrostatic current, thereby reducing the trigger voltage of the electrostatic discharge protection device, and improving the electrostatic discharge protection capability of the electrostatic discharge protection device. With the conduction of the transistor, the second P-type heavily-doped region 140, the first N well 220, the P well 210, and the first N-type heavily-doped region 120 form a low impedance channel, to discharge most of the electrostatic current, thereby further improving the electrostatic discharge protection capability of the electrostatic discharge protection device.

The embodiments or implementations of this specification are described in a progressive manner, and each embodiment focuses on differences from other embodiments. The same or similar parts between the embodiments may refer to each other.

In the descriptions of this specification, the description with reference to the term “one implementation”, “some implementations”, “an exemplary implementation”, “an example”, “a specific example” or “some examples” means that a specific feature, structure, material or characteristic described in combination with the implementation(s) or example(s) is included in at least one implementation or example of the present disclosure. In this specification, the schematic expression of the above terms does not necessarily refer to the same implementation or example. Moreover, the described specific feature, structure, material or characteristic may be combined in an appropriate manner in any one or more implementations or examples.

Finally, it should be noted that the above embodiments are merely used to explain the technical solutions of the present disclosure, but are not intended to limit the present disclosure. Although the present disclosure is described in detail with reference to the foregoing embodiments, those of ordinary skill in the art should understand that they can still modify the technical solutions described in the foregoing embodiments, or make equivalent substitutions on some or all technical features therein. These modifications or substitutions do not make the essence of the corresponding technical solutions deviate from the spirit and scope of the technical solutions of the embodiments of the present disclosure.

1. An electrostatic discharge protection device, comprising a first subdevice, the first subdevice comprising: a first P-type heavily-doped region, a first N-type heavily-doped region, a second N-type heavily-doped region, a second P-type heavily-doped region, and a third N-type heavily-doped region;
wherein both the first P-type heavily-doped region and the first N-type heavily-doped region are located in a P well, both the second P-type heavily-doped region and the third N-type heavily-doped region are located in a first N well, one part of the second N-type heavily-doped region is located in the P well, the other part of the second N-type heavily-doped region is located in the first N well, the P well is adjacent to the first N well, and both the P well and the first N well are located in a P-type substrate;
the P-type substrate is provided with a gate structure, the gate structure is located between the first N-type heavily-doped region and the second N-type heavily-doped region, and the gate structure, the first N-type heavily-doped region, and the second N-type heavily-doped region form a transistor; and
the first N-type heavily-doped region and the gate structure are connected to a first voltage, and the second N-type heavily-doped region and the second P-type heavily-doped region are connected to a second voltage.

2. The electrostatic discharge protection device according to claim 1, wherein the gate structurer is connected to the first voltage through a first resistor, and the second N-type heavily-doped region is connected to the second voltage through a second resistor.

3. The electrostatic discharge protection device according to claim 2, wherein the first voltage is a cathode voltage, and the second voltage is an anode voltage.

4. The electrostatic discharge protection device according to claim 1, wherein the P well, the first N well, and the first N-type heavily-doped region form a parasitic NPN-type transistor; and
the P well, the first N well, and the second P-type heavily-doped region form a parasitic PNP-type transistor, and the parasitic PNP-type transistor and the parasitic NPN-type transistor form a first discharge path.

5. The electrostatic discharge protection device according to claim 4, wherein the P well has a first parasitic resistor, one terminal of the first parasitic resistor is connected to a base of the parasitic NPN-type transistor, and the base of the parasitic NPN-type transistor is further connected to a collector of the parasitic PNP-type transistor.

6. The electrostatic discharge protection device according to claim 4, wherein the first N well has a second parasitic resistor, one terminal of the second parasitic resistor is connected to a base of the parasitic PNP-type transistor, and the base of the parasitic PNP-type transistor is further connected to a collector of the parasitic NPN-type transistor.

7. The electrostatic discharge protection device according to claim 1, wherein the second N-type heavily-doped region is located between the first N-type heavily-doped region and the second P-type heavily-doped region, and the second P-type heavily-doped region is located between the second N-type heavily-doped region and the third N-type heavily-doped region.

8. The electrostatic discharge protection device according to claim 1, wherein both the P well and the first N well are located in a deep N well, and the deep N well is located at the P-type substrate.

9. The electrostatic discharge protection device according to claim 8, wherein a second N well is further provided on a side of the P well far away from the first N well, the second N well is adjacent to the P well, one part of the second N well is located in the deep N well, and the other part of the second N well is located at the P-type substrate.

10. The electrostatic discharge protection device according to claim 1, wherein the first subdevice further comprises shallow trench isolation regions, and the shallow trench isolation regions are provided between the first P-type heavily-doped region and the first N-type heavily-doped region, between the second N-type heavily-doped region and the second P-type heavily-doped region, and between the second P-type heavily-doped region and the third N-type heavily-doped region.

11. The electrostatic discharge protection device according to claim 1, wherein the second P-type heavily-doped region and the second N-type heavily-doped region form a first diode, an anode of the first diode is connected to the second P-type heavily-doped region, a cathode of the first diode is connected to the second N-type heavily-doped region, and the first diode and the transistor form a second discharge path.

12. The electrostatic discharge protection device according to claim 11, wherein the first P-type heavily-doped region is electrically connected to the third N-type heavily-doped region;
the second P-type heavily-doped region and the third N-type heavily-doped region form a second diode, an anode of the second diode is connected to the second P-type heavily-doped region, and a cathode of the second diode is connected to the third N-type heavily-doped region;
the first P-type heavily-doped region and the first N-type heavily-doped region form a third diode, an anode of the third diode is connected to the first P-type heavily-doped region, and a cathode of the third diode is connected to the first N-type heavily-doped region; and
the second diode and the third diode form a third discharge path.

13. The electrostatic discharge protection device according to claim 1, wherein the electrostatic discharge protection device further comprises a second subdevice, the second subdevice has a same structure as the first subdevice, and the second subdevice and the first subdevice are symmetrically distributed with respect to an axis of symmetry.

14. The electrostatic discharge protection device according to claim 13, wherein the third N-type heavily-doped region of the first subdevice is located on a side of the first subdevice close to the axis of symmetry, and the first subdevice and the second subdevice share the third N-type heavily-doped region.

15. The electrostatic discharge protection device according to claim 14, wherein the first subdevice and the second subdevice share the first N well, and the first subdevice and the second subdevice share the P-type substrate.
